(19) United States
(12) Patent Application Publication
(10) Pub. No.: US 2012/0038244 A1
(43) Pub. Date: Feb. 16, 2012

(54) PIEZOELECTRIC VIBRATION DEVICE, METHOD OF MANUFACTURING THE SAME, AND METHOD OF ADJUSTING RESONANT FREQUENCY

(75) Inventors: Mitsuhiro WADA, Chino-shi (JP); Tatsushi KATO, Chino-shi (JP); Satoru TANAKA, Chino-shi (JP)

(73) Assignee: SEIKO EPSON CORPORATION, Tokyo (JP)

(21) Appl. No.: 13/185,984

(22) Filed: Jul. 19, 2011

(30) Foreign Application Priority Data
Aug. 16, 2010 (JP) 2010-181805
Apr. 19, 2011 (JP) 2011-093343

(51) Int. Cl. H01L 41/04; H04R 17/00

(52) U.S. Cl. 310/313 C; 29/25.35

(57) ABSTRACT

A method of manufacturing a piezoelectric vibration device having a surface acoustic wave element includes a step of forming a functional film adapted to increase a velocity of a wave on a surface of the surface acoustic wave element. Further, the Young's modulus of the functional film is higher than the Young's modulus of each of the excitation electrode and the piezoelectric body, and the density of the functional film is lower than the density of each of the excitation electrode and the piezoelectric body. Thus, it is possible to develop the frequency rise due to the elastic modulus rise while suppressing the influence of the frequency drop due to the mass attachment effect to thereby raise the resonant frequency of the surface acoustic wave element.

The entire disclosure of Japanese Patent Application No. 2010-181805, filed Aug. 16, 2010 and Japanese Patent Application No. 2011-093343, filed Apr. 19, 2011 are expressly incorporated by reference herein.

### BACKGROUND

1. Technical Field

The present invention relates to a piezoelectric vibration device, a method of manufacturing the piezoelectric vibration device, and a method of adjusting the resonant frequency.

2. Related Art

In various electronic devices such as communication devices, computers, or mobile devices, there is used a piezoelectric vibration device having a surface acoustic wave (SAW) element as an electronic component such as a vibrator, an oscillator, or a filter. The piezoelectric vibration devices assume the role of vibrator/filter for transmitting/receiving sync signals and only the signals with appropriate frequencies of electronic devices, and therefore, the accuracy of the SAW resonant frequency to the base thereof is important.

However, since each SAW element includes production tolerance (e.g., tolerance in the manufacturing dimension or mass of the piezoelectric body, and tolerance in the manufacturing dimension or mass of the electrode), it results that a deviation from the design value is caused in the resonant frequency of each SAW element. Therefore, the manufacturers of quartz crystal devices perform frequency adjustment on each SAW element to thereby tune the frequency to a predetermined value, and further provide airtight sealing so that the frequency does not vary for a long period of time.

Here, the methods of adjusting the frequency of the SAW element can be divided into two major types.

In the first method, a metal film or metal fine particles made of gold (Au) are formed on the surface of the SAW element using a vapor-deposition method or a sputtering method to thereby perform mass attachment to the vibrating body (i.e., the piezoelectric body). Thus, the frequency is lowered (see, e.g., JP-A-2007-53520).

Further, in the second method, a part of the excitation electrode on the surface of the SAW element or a part of the quartz crystal is physically (or chemically) scraped away by sputtering-out (or etching) by irradiating the SAW element with an ion beam or acting the gas plasma on the SAW element to thereby perform mass reduction of the vibrating body. Thus, the frequency is raised (see, e.g., JP-A-2009-141825, JP-A-5-63485).

Incidentally, according to the first method described above, since the frequency can only be lowered, if the frequency is lowered beyond the desired value by chance, it is not possible to restore the production lot, which causes degradation of production yield.

Further, according to the second method, it results that the part of the SAW element is destroyed in the elementary sense. Therefore, it results that the roughness of the excitation electrode surface of the SAW element and the quartz crystal surface is increased, and thus, the possibility of deterioration of the frequency characteristics arises. Further, in some cases, the excitation electrode surface of the SAW element and the quartz crystal surface might be provided with an insulating thin film for preventing the electrical short due to a foreign matter between the excitation electrodes or a thin film for maintaining long-term reliability of the frequency of the SAW oscillator (as such thin films, a water-repellent thin film and an oil-repellent thin film for preventing moisture or organic component from adhering to the SAW chip to decompose or contaminate the SAW chip can be cited). In this case, due to the ion beam irradiation or the plasma etching on the thin film having been formed while taking the trouble, there is a possibility that the thin film causes structural breakage, and fails to sufficiently exert the insulating property, the water repellency, the oil repellency, and so on.

On the other hand, it is also possible to adopt a method of using a combination of the first and second methods as the method of adjusting the frequency. In this case, the problem of the “one-way” property of the frequency adjustment (i.e., the problem that the frequency can only be lowered, or can only be raised) can be avoided. However, as described above, in the case of raising the frequency, there still remains the problem of, for example, the deterioration of the frequency characteristics due to the increase in the surface roughness, and the degradation of the insulating property, the water repellency, and the oil repellency due to the structural breakage.

### SUMMARY

An advantage of some aspects of the invention is to provide a piezoelectric vibration device arranged to be capable of raising the resonant frequency while preventing the increase in the surface roughness and the structural breakage, a method of manufacturing the piezoelectric vibration device, and a method of adjusting the resonant frequency.

An aspect of the invention is directed to a method of manufacturing a piezoelectric vibration device having a surface acoustic wave element including: forming a functional film adapted to increase a velocity of a wave on a surface of the surface acoustic wave element.

Here, assuming that the velocity of the “wave” is v, the frequency thereof is f, and the wavelength thereof is λ, the relationship of formula 1 is true between these parameters.

f=v/λ (1)

According to such a method, the resonant frequency of the surface acoustic wave element can be raised using the relationship of the formula 1. There is no need for scraping away the surface of the surface acoustic wave element using a physical or chemical measure such as sputtering-out by ion beam irradiation on the surface of the surface acoustic wave element or etching by gas plasma when adjusting the resonant frequency. Therefore, it is possible to raise the resonant frequency while preventing the increase in the surface roughness of the surface acoustic wave element and the structural breakage.

Further, in the method of manufacturing a piezoelectric vibration device described above, it is also possible that the surface acoustic wave element includes a piezoelectric body and an excitation electrode formed on the piezoelectric body, a Young's modulus of the functional film is higher than a Young's modulus of each of the excitation electrode and the piezoelectric body, and a density of the functional film is lower than a density of each of the excitation electrode and the piezoelectric body.

Here, the property of the wave excited by the surface acoustic wave element (i.e., the surface acoustic wave) depends on the physical properties of the medium on which the wave propagates, and in particular on the physical properties of the portion near to the surface. Assuming in the surface acoustic wave element that the frequency of the wave to be excited is f, the elastic modulus of the medium is E, and the density of the medium is ρ, the relationship of the formula 2 is true between these parameters.

f∝√(E/ρ) (2)

The inventors have found the fact that the elastic modulus of the medium, on which the surface acoustic wave propagates, rises by forming the film having the Young's modulus higher than that of the piezoelectric body and the excitation electrode on the surface of the surface acoustic wave element, and as a result, and the resonant frequency of the surface acoustic wave element rises in some cases. On the other hand, it is known that, since the film is formed, there arises the phenomenon that the resonant frequency of the surface acoustic element drops due to the mass attachment to the vibrating body as commonly known. Therefore, the inventors have focused attention on the density in order for reduce the drop of the resonant frequency due to the mass attachment.

By forming the functional film having the “high Young's modulus” and the “low density” on the surface of the surface acoustic wave element, it is possible to develop the frequency rise due to the elastic modulus rise while suppressing the influence of the frequency drop due to the mass attachment effect to thereby raise the resonant frequency.

Further, in the method of manufacturing a piezoelectric vibration device described above, it is also possible that the surface acoustic wave element includes a piezoelectric body and an excitation electrode formed on the piezoelectric body, the excitation electrode is an interdigital transducer made of one of aluminum and aluminum alloy, the piezoelectric body is a quartz crystal substrate, a Young's modulus of the functional film is one of equal to and higher than 50 GPa, and a density of the functional film is one of equal to and lower than 1.0 g/cm³. According to such a method, the resonant frequency of the surface acoustic wave element can be raised as shown in, for example, FIG. 6.

Further, in the method of manufacturing a piezoelectric vibration device described above, it is also possible that the surface acoustic wave element includes a piezoelectric body and an excitation electrode formed on the piezoelectric body, the excitation electrode is an interdigital transducer made of one of aluminum and aluminum alloy, the piezoelectric body is a quartz crystal substrate, a Young's modulus of the functional film is one of equal to and higher than 80 GPa, and a density of the functional film is one of equal to and lower than 2.0 g/cm³. According to such a method, the resonant frequency of the surface acoustic wave element can be raised as shown in, for example, FIG. 6.

Further, in the method of manufacturing a piezoelectric vibration device described above, it is also possible that the surface acoustic wave element includes a piezoelectric body and an excitation electrode formed on the piezoelectric body, the excitation electrode is an interdigital transducer made of one of aluminum and aluminum alloy, the piezoelectric body is a quartz crystal substrate, a Young's modulus of the functional film is one of equal to and higher than 150 GPa, and a density of the functional film is one of equal to and lower than 4.0 g/cm³. According to such a method, the resonant frequency of the surface acoustic wave element can be raised as shown in, for example, FIG. 6.

Further, in the method of manufacturing a piezoelectric vibration device described above, it is also possible that there is further provided with measuring, prior to the forming a functional film, a resonant frequency of the surface acoustic wave element with a voltage applied to the excitation electrode, and in the forming a functional film, a thickness of the functional film is adjusted based on a measurement value of the resonant frequency. According to such a method, the resonant frequency of the surface acoustic wave element can be adjusted to a desired value.

Further, in the method of manufacturing a piezoelectric vibration device described above, it is also possible that there is further provided with: forming, prior to the measuring a resonant frequency, one of an insulating film, a water-repellent film, and an oil-repellent film on a surface of the surface acoustic wave element, and in the measuring a resonant frequency, the resonant frequency is measured in a condition in which one of the insulating film, the water-repellent film, and the oil-repellent film is formed, and in the forming a functional film, the functional film is formed on one of the insulating film, the water-repellent film, and the oil-repellent film. According to such a method, the electrical short between the excitation electrodes of the surface acoustic wave element, the corrosion or the contamination due to moisture or an organic component can be prevented. Further, since the sputtering-out by the ion beam irradiation, the etching by the gas plasma, or the like for raising the resonant frequency of the surface acoustic, element is not performed, the structural breakage can also be prevented with respect to this film. It should be noted that “one of the insulating film, the water-repellent film, and the oil-repellent film” corresponds to, for example, a thin film 5 described later.

Another aspect of the invention is directed to a piezoelectric vibration device having a surface acoustic wave element including a functional film formed on a surface of the surface acoustic wave element, wherein the functional film has a function of increasing a velocity of a wave. According to such a configuration, it is possible to raise the resonant frequency while preventing the increase in the surface roughness of the surface acoustic wave element and the structural breakage.

Further, in the piezoelectric vibration device described above, it is also possible that the surface acoustic wave element includes a piezoelectric body and an excitation electrode formed on the piezoelectric body, a Young's modulus of the functional film is higher than a Young's modulus of each of the excitation electrode and the piezoelectric body, and a density of the functional film is lower than a density of each of the excitation electrode and the piezoelectric body.

Further, in the piezoelectric vibration device described above, it is also possible that the surface acoustic wave element includes a piezoelectric body and an excitation electrode formed on the piezoelectric body, the excitation electrode is an interdigital transducer made of one of aluminum and aluminum alloy, the piezoelectric body is a quartz crystal substrate, a Young's modulus of the functional film is one of equal to and higher than 50 GPa, and a density of the functional film is one of equal to and lower than 1.0 g/cm³.

Further, in the piezoelectric vibration device described above, it is also possible that the surface acoustic wave element includes a piezoelectric body and an excitation electrode formed on the piezoelectric body, the excitation electrode is an interdigital transducer made of one of aluminum and aluminum alloy, the piezoelectric body is a quartz crystal substrate, a Young's modulus of the functional film is one of equal to and higher than 80 GPa, and a density of the functional film is one of equal to and lower than 2.0 g/cm³.

Further, in the piezoelectric vibration device described above, it is also possible that the surface acoustic wave element includes a piezoelectric body and an excitation electrode formed on the piezoelectric body, the excitation electrode is an interdigital transducer made of one of aluminum and aluminum alloy, the piezoelectric body is a quartz crystal substrate, a Young's modulus of the functional film is one of equal to and higher than 150 GPa, and a density of the functional film is one of equal to and lower than 4.0 g/cm³.

Further, in the piezoelectric vibration device described above, it is also possible that there is further provided one of an insulating film, a water-repellent film, and an oil-repellent film formed on a surface of the surface acoustic wave element, and the functional film is formed on one of the insulating film, the water-repellent film, and the oil-repellent film.

Still another aspect of the invention is directed to a method of adjusting a resonant frequency of a surface acoustic wave element, including raising the resonant frequency by forming a functional film adapted to increase a velocity of a wave on a surface of the surface acoustic wave element. According to such a method, it is possible to raise the resonant frequency while preventing the increase in the surface roughness of the surface acoustic wave element and the structural breakage.

### BRIEF DESCRIPTION OF THE DRAWINGS

The invention will be described with reference to the accompanying drawings, wherein like numbers reference like elements.

FIGS. 1A and 1B are diagrams showing a configuration example of a SAW element according to an embodiment of the invention.

FIG. 2 is a diagram showing a configuration example of a piezoelectric device according to the embodiment of the invention.

FIG. 3 is a flowchart showing a method of manufacturing the piezoelectric vibration device.

FIG. 4 is a diagram showing a configuration example of a deposition device according to the embodiment of the invention.

FIG. 5 is a chart showing a simulation result of a relationship between the thickness of a functional film and the resonant frequency.

FIG. 6 is a chart showing a simulation result of a relationship between the physical properties of the functional film and the resonant frequency.

FIGS. 7A and 7B are diagrams showing another configuration example of the SAW element (part 1).

FIGS. 8A and 8B are diagrams showing another configuration example of the SAW element (part 2).

FIG. 9 is a diagram showing another configuration example of the SAW element (part 3).

FIG. 10 is a diagram showing another configuration example of the SAW element (part 4).

FIG. 11 is a diagram showing another configuration example of the SAW element (part 5).

### DESCRIPTION OF AN EXEMPLARY EMBODIMENT

An embodiment of the invention will hereinafter be explained with reference to the accompanying drawings. It should be noted that in the drawings hereinafter explained, the parts having the same configurations are provided with the same reference numerals, and duplicated explanations therefor will be omitted.

### 1. Regarding Configuration Example of Piezoelectric Vibration Device

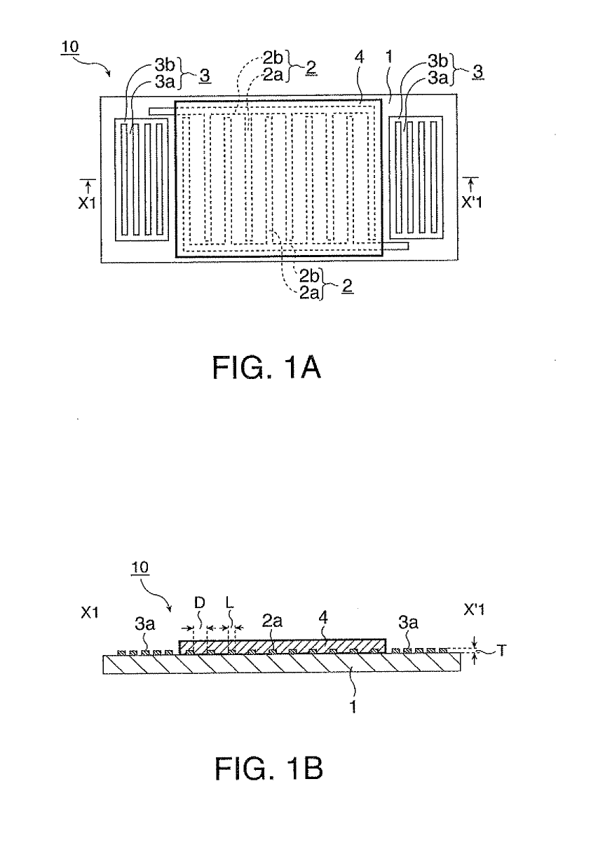

FIGS. 1A and 1B are diagrams showing a configuration example of a surface acoustic wave (i.e., SAW) element 10 according to the embodiment of the invention, wherein FIG. 1A is a plan view, and FIG. 1B is a cross-sectional view obtained by cutting the plan view of FIG. 1A along a line X1-X′1.

As shown in FIGS. 1A and 1B, the SAW element 10 is formed on the surface of the piezoelectric body 1, and is provided with excitation electrodes 2 and reflectors 3 formed on the surface of the piezoelectric body 1, and a functional film 4 formed on the surface of the piezoelectric body 1 so as to cover the excitation electrodes 2. The piezoelectric body 1 is a substrate, the SAW of which is excited in response to application of a voltage, and is formed of, for example, an ST-cut quartz crystal substrate.

The excitation electrodes 2 are electrodes for receiving a supply of a drive voltage and applying the voltage to the piezoelectric body 1, and are formed of, for example, interdigital transducers (IDT). The interdigital transducers are each formed of a combination of a plurality of electrode fingers 2a disposed so as to be perpendicular to the propagation direction of the surface acoustic wave and a bus bar 2b disposed along the propagation direction of the surface acoustic wave and for connecting the electrode fingers 2a to each other. Two such interdigital transducers form a pair, and are disposed so that the electrode fingers 2a of one of the pair and the electrode fingers 2a of the other of the pair mesh with each other alternately in a plan view. As shown in FIG. 1B, assuming that the electrode width of the electrode fingers 2a is L, the thickness of the electrode fingers 2a is T, and the distance between the electrode fingers 2a is D, these values are set to, for example, L=2.5 μm, T=158 nm, and D=1.4 μm.

The reflectors 3 are disposed so as to sandwich the excitation electrodes 2 on the both sides thereof in a plan view, and are electrodes for reflecting the SAW (between the reflectors 3) excited by the excitation electrodes 2 to thereby keep the SAW therebetween. The reflectors 3 are each formed of a combination of, for example, a plurality of conductor strips 3a disposed so as to be parallel to the electrode fingers 2a, and bus bars 3b for respectively connecting the both ends of the conductor strips 3a. The excitation electrodes 2 and the reflectors 3 are made of, for example, aluminum or aluminum alloy.

Further, the functional film 4 is a film having a function of increasing the velocity of the SAW. The functional film 4 is formed on the surface of the piezoelectric body 1 so as to entirely cover the electrode fingers 2a of the excitation electrodes 2, for example. Here, the relationship of the formula 1 described above is true between the velocity v of a wave and the frequency f of the wave. By making the SAW propagate to the functional film 4, rising of the resonant frequency of the SAW element 10 is achieved.

Citing an example of the physical properties of the functional film 4, the Young's modulus of the functional film 4 is set higher than the Young' modulus of both of the piezoelectric body 1 and the excitation electrodes 2, and at the same time, the density of the functional film 4 is set lower than the density of both of the piezoelectric body 1 and the excitation electrodes 2. For example, if the piezoelectric body 1 is made of a quartz crystal (the Young's modulus of 73 GPa, the density of 2.6 g/cm³), and the excitation electrodes 2 are made of aluminum (the Young's modulus of 70 GPa, the density of 2.7 g/cm³), a hard carbon film, a beryllium film, and so on described later can be cited as the functional film 4 fulfilling the physical properties described above. As described above, by limiting the material physical properties of the functional film 4 in conjunction with the materials of the piezoelectric body 1 and the excitation electrodes 2, it is possible to develop the rising of the frequency due to the high elastic modulus while suppressing the influence of the frequency drop due to the mass attachment effect to thereby raise the resonant frequency of the SAW element 10.

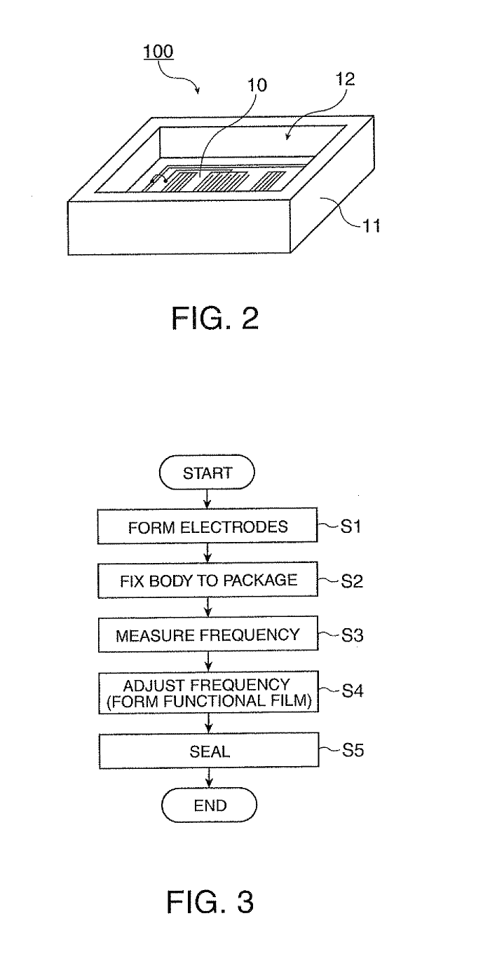

It should be noted that the SAW element 10 exerts a function of outputting an alternating current with a designed frequency if combined with an oscillator circuit not shown. As shown in FIG. 2, for example, in the piezoelectric vibration device 100 having the SAW element 10, the SAW element 10 is fixed inside the package 11, and an opening side 12 of the package 11 is covered by a cap not shown. The inside of the package 11 covered by the cap is sealed in a vacuum state or in an inert gas atmosphere, and thus ensuring of the long-term reliability of the oscillation frequency is achieved.

Then, a method of manufacturing the piezoelectric vibration device 100 will be explained.

### 2. Regarding Method of Manufacturing Piezoelectric Vibration Device

FIG. 3 is a flowchart showing the method of manufacturing the piezoelectric vibration device 100 according to the embodiment of the invention. It should be noted that in this example it is assumed that the relationship between the film thickness of the functional film 4 to be formed on the surface of the SAW element 10 and the resonant frequency of the SAW element 10 is previously obtained by a simulation, an experiment, or the like as shown in, for example, FIG. 5 described later.

First of all, in the step S1 of FIG. 3, the excitation electrodes 2 and the reflectors 3 are formed on the surface of the piezoelectric body 1. For example, the conductive film made of aluminum or aluminum alloy is formed on the surface of the piezoelectric body 1. Subsequently, the conductive film is patterned using the photolithography technology and the etching technology. Thus, the excitation electrodes 2 and the reflectors 3 are simultaneously formed on the surface of the piezoelectric body 1. The sputtering method, for example, is used as the method of forming the conductive film. As the method of etching the conductive film, there can be used the dry etching such as the reactive ion etching (RIE) or the plasma etching, or the wet etching.

Alternatively, it is also possible to arrange that the excitation electrodes 2 and the reflectors 3 are formed using the print method in the step S1. For example, it is also possible to arrange that the ink including conductive particles made of, for example, aluminum is sprayed onto the surface of the piezoelectric body 1 to thereby form the excitation electrodes 2 and the reflectors 3.

Subsequently, in the step S2 of FIG. 3, the piezoelectric body 1 (i.e., the SAW element 10) provided with the excitation electrodes 2 and the reflector 3 are housed inside the package 11, and then fixed.

Subsequently, in the step S3 of FIG. 3, the drive voltage is applied to the excitation electrodes 2 to thereby excite the SAW, and then the resonant frequency thereof is measured. It should be noted that in the present example it is assumed that the shape and the dimensions of the excitation electrodes 2 (e.g., the electrode width L of the electrode fingers 2a, the thickness T of the electrode fingers 2a, and the distance D between the electrode fingers 2a in the interdigital transducer) are set so that the resonant frequency before forming the functional film 4 takes a value roughly lower than the target value subsequently, in the step S4 of FIG. 3, adjustment for eliminating the difference between the measurement value and the target value is performed on the resonant frequency. Specifically, the film thickness of the functional film 4 necessary for eliminating the difference between the target value of the resonant frequency and the measurement value measured in the step S3 is calculated. Then, the functional film 4 is formed on the surface of the SAW element to have a thickness corresponding to the film thickness thus obtained by the calculation. Thus, the resonant frequency is raised to thereby adjust the value thereof to the target value. As the method of forming the functional film 4, there can be used, for example, a sputtering method, a vapor deposition method, a chemical vapor deposition (CVD) method, and so on.

Subsequently, in the step S5 of FIG. 3, the cap is attached to the opening side 12 of the package 11 in a chamber in the vacuum state or in an inert gas atmosphere to thereby seal the inside of the package 11. Thus, the piezoelectric vibration device 100 shown in FIG. 2 is completed.

### 3. Regarding Deposition Device of Functional Film

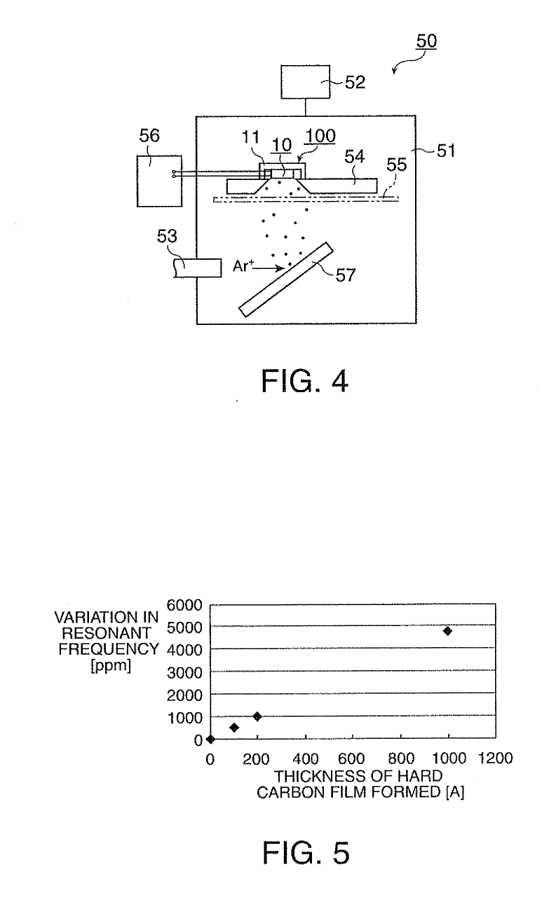

For the measurement of the resonant frequency in the step S3 of FIG. 3 and the adjustment (i.e., the formation of the functional film 4) of the resonant frequency in the step S4, a deposition device 50 having a frequency measurement function shown in FIG. 4, for example, can be used.

FIG. 4 is a conceptual diagram showing a configuration example of the deposition device 50 according to the embodiment of the invention.

As shown in FIG. 4, the deposition device 50 uses, for example, the ion beam sputtering method, and has a chamber 51, an air displacement pump 52 for discharging the air in the chamber 51 to thereby create the vacuum condition, an ion gun 53 for accelerating the ions and discharging the ions in the chamber 51 in the vacuum condition, a mask 54, a shutter 55, and a frequency measuring instrument 56. Further, a target 57 such as hard carbon is disposed in the chamber 51.

In the deposition device 50, the frequency measuring instrument 56 measures the resonant frequency of the SAW element when measuring the frequency (e.g., the step S3 of FIG. 3). Further, when depositing the functional film 4 (e.g., the step S4 of FIG. 3), the shutter 55 is opened to set the condition in which the opening side of the package 11 is exposed to the target 57. In this condition, the ion gun 53 emits the ions toward the target 57. The ions are, for example, argon ions (Ar⁺). When the ion collides with the target 57, the recoil makes the material atom of the target 57 jump out. The atom thus jumping out adheres to the surface of the SAW element 10 to thereby deposit the functional film 4 on the surface. Since the irradiation time of the ion and the deposition thickness of the functional film 4 are proportional to each other, the functional film 4 can be formed to have a desired thickness by controlling the irradiation time of the ion (or by controlling the open time of the shutter 55). Further, in the present example, the mask 54 blocks the deposition of the functional film 4 to the area other than the surface of the SAW element 10.

It should be noted that it is also possible for the deposition device 50 to perform the deposition of the functional film 4 on the surface of the SAW element 10 while measuring the resonant frequency of the SAW element 10 with the frequency measuring instrument 56. In other words, it is also possible to simultaneously perform the step S3 and the step S4 of FIG. 3 in parallel to each other. In this case, the resonant frequency of the SAW element 10 can be adjusted to the target value by stopping the ion irradiation with the ion gun 53 (or closing the shutter 55) at the time when the resonant frequency reaches the target value.

### 4. Regarding Simulation Result

### 4-1. Regarding Relationship Between Film Thickness of Functional Film and Resonant Frequency

FIG. 5 shows a result of the simulation of the relationship between the film thickness of the functional film and the resonant frequency using the finite element method. The vertical axis of FIG. 5 represents the variation of the resonant frequency. The unit thereof is parts per million (ppm). Further, the lateral axis of FIG. 5 represents the film thickness of the functional film thus formed.

The material, the size, and so on of the SAW element used in the simulation as a model are substantially the same as those of the SAW element 10 explained in the column of “1. Regarding Configuration Example of Piezoelectric Vibration Device” described above, and are specifically as follows.
Piezoelectric body: ST-cut quartz crystal substrate
Shape and size of the excitation electrodes: interdigital transducer (electrode width of the electrode fingers L=2.5 μm; thickness of the electrode fingers T=158 nm; distance between the electrode fingers D=1.4 μm)
Material of the excitation electrodes and the reflectors: aluminum
Type of the functional film: hard carbon film (diamond-like carbon; density of 1.5 g/cm³; Young's modulus of 100 GPa)
Formation area of the functional film: on the surface of the ST-cut quartz crystal substrate including the excitation electrodes
Reference value (in the condition without forming the functional film) of the resonant frequency: 410 MHz

As shown in FIG. 5, according to the result of the present simulation, if the hard carbon film with the thickness of 100 Å is formed, the result of the adjustment of the frequency is +510 ppm (+0.21 MHz). Further, if the hard carbon film with the thickness of 200 Å is formed, the result of the adjustment of the frequency is +1011 ppm (+0.42 MHz). The result shows the fact that the proportional relationship is true between the film thickness of the functional film and the variation in the resonant frequency, and therefore, an amount of rising of the resonant frequency can be controlled by controlling the film thickness of the functional film (using, for example, the sputtering deposition conditions).

### 4-2. Regarding Relationship Between Physical Properties of Functional Film and Resonant Frequency

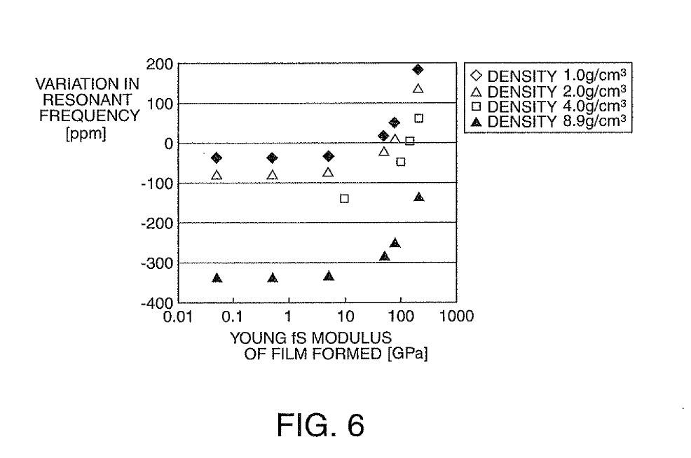

FIG. 6 shows a result of the simulation of the relationship between the physical properties (the density and the Young's modulus) of the functional film and the resonant frequency using the finite element method. The vertical axis of FIG. 6 represents the variation of the resonant frequency. The unit thereof is parts per million (ppm). Further, the lateral axis of FIG. 6 represents the Young's modulus of the functional film.

The material, the size, and so on of the SAW element used in the simulation as a model are substantially the same as those of the SAW element explained in the column of “4-1. Regarding Relationship Between Film Thickness of Functional Film and Resonant Frequency” described above. It should be noted that the physical properties and the thickness of the functional film thus formed are different from those described above, and are specifically set as described below.
Density of the functional film: 4 levels (1.0 g/cm³, 2.0 g/cm³, 4.0 g/cm³, and 8.9 g/cm³)
Young's modulus of the functional film: in a range of 0.01 through 1000 GPa
Thickness of the functional film thus formed: 10 Å

As shown in FIG. 6, the result of the present simulation shows the fact that rising of the resonant frequency occurs in the area in which the Young's modulus of the film thus formed is high and the density of the film thus formed is low. Further, according to the result of the simulation, there is obtained the findings that if the SAW element has the configuration described above (if at least the piezoelectric body consists of a quartz crystal, and the excitation electrodes are formed of the interdigital transducers made of aluminum or aluminum alloy), it is sufficient for the functional film to have the physical properties described in either one of the alternatives (a) through (c) described below in order for developing the effect of raising the resonant frequency due to the formation of the functional film.

(a) The Young's modulus of the functional film is equal to or higher than 50 GPa, and the density thereof is equal to or lower than 1.0 g/cm³.
(b) The Young's modulus of the functional film is equal to or higher than 80 GPa, and the density thereof is equal to or lower than 2.0 g/cm³.
(c) The Young's modulus of the functional film is equal to or higher than 150 GPa, and the density thereof is equal to or lower than 4.0 g/cm³.

As the film having such physical properties, the following films, for example, can be cited.
Hard carbon film (diamond-like carbon; Young's modulus of 100 through 760 GPa, density of 1.2 through 3.3 g/cm³)
Silicon nitride (Young's modulus of 290 GPa, density of 3.2 g/cm³)
Aluminum nitride (Young's modulus of 280 GPa, density of 3.3 g/cm³)
Silicon carbide (Young's modulus of 410 GPa, density of 3.2 g/cm³)
Boron carbide (Young's modulus of 450 GPa, density of 2.5 g/cm³)
Silicon (Young's modulus of 130 through 180 GPa, density of 2.3 g/cm³)
Diamond (Young's modulus of 1000 GPa, density of 3.5 g/cm³)
Beryllium (Young's modulus of 287 GPa, density of 1.8 g/cm³)

It should be noted that if the type of the functional film is changed, the adjustment amount of the frequency varies in accordance with the density and the Young's modulus of the film thus formed even if the thickness of the film thus formed is the same. Therefore, the adjustment sensitivity of the resonant frequency can be varied by selecting the type of the functional film. For example, the coarse adjustment and the fine adjustment of the resonant frequency can selectively be performed due to the selection of the type of the functional film.

As explained hereinabove, according to the embodiment of the invention, by forming the functional film 4 for increasing the velocity of the wave on the surface of the SAW element 10, the resonant frequency of the SAW element 10 can be raised. As such a functional film 4, there can be cited those having the Young's modulus higher than those of the piezoelectric body 1 and the excitation electrodes 2, and the density lower than those of the piezoelectric body 1 and the excitation electrodes 2. Alternatively, even if the physical properties are slightly different from the physical properties described above, the film having the physical properties of either one of the alternatives (a) through (c) described above can be used as the functional film 4 providing the piezoelectric body 1 consists of a quartz crystal and the excitation electrodes 2 are formed of the interdigital transducers made of aluminum or aluminum alloy. Thus, the resonant frequency of the SAW element 10 can be raised while preventing the increase in the surface roughness and the structural breakage compared to the related art (i.e., the second method explained in the column of the related art).

Specifically, according to the embodiment of the invention, there is no need for partially scraping away the surface of the SAW element 10 with a physical or chemical measure such as sputtering-out by ion beam irradiation on the surface of the SAW element 10 or etching by gas plasma when raising the resonant frequency of the SAW element 10. Therefore, the SAW element 10 with preferable frequency characteristics can be manufactured without causing any deterioration of the frequency characteristics due to the increase in the surface roughness of the piezoelectric body 1 and the excitation electrodes 2 and the structural breakage.

### 5. Regarding Other Embodiments

### 5-1. Regarding Formation Area of Functional Film

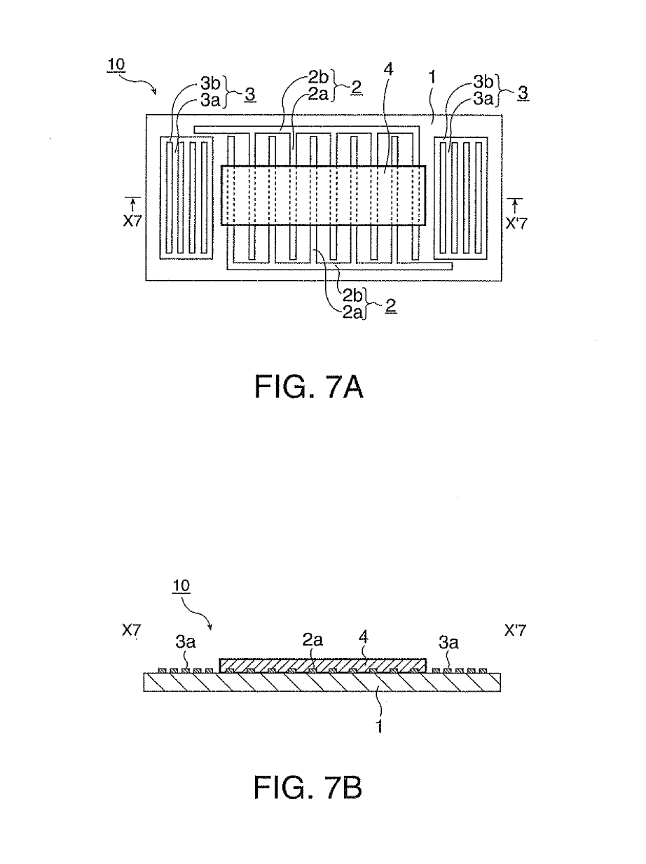

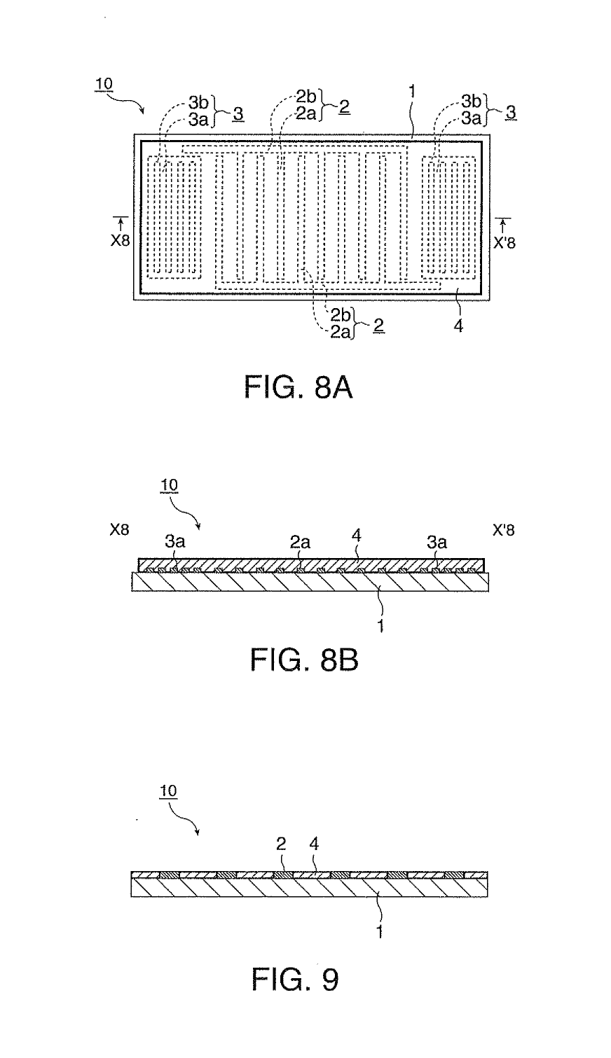

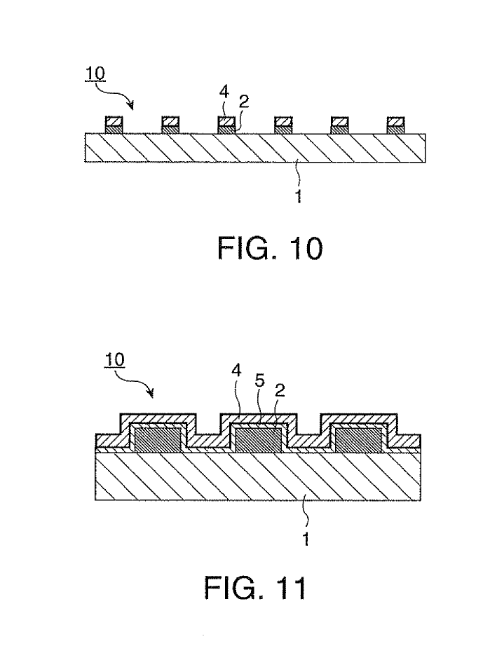

In the description of the above embodiment, the case of forming the functional film 4 so as to cover the entire electrode fingers 2a of the excitation electrodes 2 is explained. However, the invention is not at all limited thereto. It is also possible to form the functional film so as to partially cover the electrode fingers 2a as shown in, for example, FIGS. 7A and 73. Alternatively, it is also possible to form the functional film 4 so as to cover not only the excitation electrodes 2, but also the reflectors 3 as shown in, for example, FIGS. 8A and 8B. Alternatively, it is also possible to form the functional film 4 so as to cover only the portions of the surface of the piezoelectric body 1 exposed from the excitation electrodes 2 as shown in, for example, FIG. 9. Further, it is also possible to form the functional film 4 so as to cover only the surface of the excitation electrodes 2 as shown in FIG. 10. According to the findings of the inventors of the invention, the resonant frequency of the SAW element 10 can be raised also in such cases as described above.

### 5-2. Regarding Formation of Insulating Thin Film, and Water-Repellent Thin Film/Oil-Repellent Thin Film

Further, in the description of the above embodiment, the case of forming the functional film 4 directly on the surface of the piezoelectric body 1 provided with the excitation electrodes 2 and the reflectors 3 is explained. However, the invention is not at all limited thereto. It is also possible to form the insulating, water-repellent, or oil-repellent thin film 5 on the surface of the piezoelectric body 1 provided with the excitation electrodes 2, and then form the functional film 4 on the thin film 5. In other words, it is also possible to form the functional film 4 on the surface of the SAW element 10 via the thin film 5.

In this case, the resonant frequency is measured in, for example, the step S3 of FIG. 3 in the condition in which the thin film 5 described above is formed. Then, the thickness of the functional film 4 to be formed is adjusted based on the measurement value in the step S4 of FIG. 3. According to the findings of the inventors of the invention, the resonant frequency of the SAW element 10 can be raised, and adjusted to a desired value also in such cases as described above.

By forming the thin film 5, the electrical short between the excitation electrodes 2 forming a pair, the corrosion or the contamination due to moisture or an organic component can be prevented. Further, since the sputtering-out by the ion beam irradiation, the etching by the gas plasma, or the like for raising the resonant frequency of the SAW element 10 is not performed, the structural breakage of the thin film 5 can also be prevented.

### 5-3. Regarding Elimination of One-Way Property of Frequency Adjustment

Further, according to the invention, it is also possible to use both of the formation of the functional film 4 explained in the description of the above embodiment and the first method explained in the column of the related art. For example, it is also possible to form the functional film 4 to thereby raise the resonant frequency if the measurement value of the resonant frequency is lower than the target value in the step S4 of FIG. 3, and to form a metal film (not shown) for mass attachment on the surface of the SAW element to thereby lower the resonant frequency if, in contrast, the measurement value is higher than the target value. According to such a method, it is possible to adjust the resonant frequency in arbitrary directions while preventing the increase in the surface roughness and the structural breakage, and thus, the one-way property of the frequency adjustment can be eliminated.

The application range of the invention is not at all limited to the embodiments described hereinabove. The invention can widely be applied within the scope or the spirit described in the present specification. The invention can be applied to, for example, the SAW element using the quarts crystal obtained by cutting another plane, the SAW element using other piezoelectric materials such as aluminum nitride, lithium niobate, or lithium tantalate, and the SAW element using the film made of the materials described above.

What is claimed is:

1. A method of manufacturing a piezoelectric vibration device having a surface acoustic wave element, comprising:
forming a functional film that increases a velocity of a surface acoustic wave of a surface of the surface acoustic wave element.

2. The method of manufacturing a piezoelectric vibration device according to claim 1,
the surface acoustic wave element including a piezoelectric body and an excitation electrode disposed on the piezoelectric body,
a Young's modulus of the functional film being higher than a Young's modulus of the excitation electrode and the piezoelectric body, and
a density of the functional film being lower than a density of the excitation electrode and the piezoelectric body.

3. The method of manufacturing a piezoelectric vibration device according to claim 1,
the surface acoustic wave element including a piezoelectric body and an excitation electrode disposed on the piezoelectric body,
the excitation electrode including one of aluminum and aluminum alloy,
the piezoelectric body being a quartz crystal,
a Young's modulus of the functional film being 50 GPa or more, and
a density of the functional film being 1.0 g/cm³ or less.

4. The method of manufacturing a piezoelectric vibration device according to claim 1,
the surface acoustic wave element including a piezoelectric body and an excitation electrode disposed on the piezoelectric body,
the excitation electrode including one of aluminum and aluminum alloy,
the piezoelectric body being a quartz crystal,
a Young's modulus of the functional film being 80 GPa or more, and
a density of the functional film being 2.0 g/cm³ or less.

5. The method of manufacturing a piezoelectric vibration device according to claim 1,
the surface acoustic wave element including a piezoelectric body and an excitation electrode disposed on the piezoelectric body,
the excitation electrode including aluminum and aluminum alloy,
the piezoelectric body being a quartz crystal, a Young's modulus of the functional film being 150 GPa or more, and
a density of the functional film being 4.0 g/cm³ or less.

6. The method of manufacturing a piezoelectric vibration device according to claim 2, further comprising:
prior to the forming the functional film, measuring a resonant frequency of the surface acoustic wave element by applying a voltage to the excitation electrode,
the forming the functional film including adjusting a thickness of the functional film based on the resonant frequency.

7. The method of manufacturing a piezoelectric vibration device according to claim 6, further comprising:
forming, prior to the measuring a resonant frequency, one of an insulating film, a water-repellent film, and an oil-repellent film on a surface of the surface acoustic wave element,
the measuring the resonant frequency, the resonant frequency being measured in a condition in which one of the insulating film, the water-repellent film, and the oil-repellent film is formed, and
the forming the functional film including forming the functional film on one of the insulating film, the water-repellent film, and the oil-repellent film.

8. A piezoelectric vibration device, comprising:
a surface acoustic wave element; and
a functional film disposed on a surface of the surface acoustic wave element,
the functional film having a function of increasing a velocity of a surface acoustic wave.

9. The piezoelectric vibration device according to claim 8,
the surface acoustic wave element including a piezoelectric body and an excitation electrode disposed on the piezoelectric body,
a Young's modulus of the functional film being higher than a Young's modulus of the excitation electrode and the piezoelectric body, and
a density of the functional film being lower than a density of the excitation electrode and the piezoelectric body.

10. The piezoelectric vibration device according to claim 8,
the surface acoustic wave element including a piezoelectric body and an excitation electrode disposed on the piezoelectric body,
the excitation electrode including one of aluminum and aluminum alloy,
the piezoelectric body being a quartz crystal,
a Young's modulus of the functional film being 50 GPa or more, and
a density of the functional film being 1.0 g/cm³ or less.

11. The piezoelectric vibration device according to claim 8,
the surface acoustic wave element including a piezoelectric body and an excitation electrode disposed on the piezoelectric body,
the excitation electrode including aluminum and aluminum alloy,
the piezoelectric body being a quartz crystal,
a Young's modulus of the functional film being 80 GPa or more, and
a density of the functional film being 2.0 g/cm³ or less.

12. The piezoelectric vibration device according to claim 8,
the surface acoustic wave element including a piezoelectric body and an excitation electrode disposed on the piezoelectric body,
the excitation electrode including one of aluminum and aluminum alloy,
the piezoelectric body being a quartz crystal,
a Young's modulus of the functional film being 150 GPa or more, and
a density of the functional film being 4.0 g/cm³ or less.

13. The piezoelectric vibration device according to claim 9, further comprising:
one of an insulating film, a water-repellent film, and an oil-repellent film disposed on a surface of the surface acoustic wave element,
the functional film being disposed on one of the insulating film, the water-repellent film, and the oil-repellent film.

14. A method of adjusting a resonant frequency of a surface acoustic wave element, comprising:
raising the resonant frequency by forming a functional film that increases a velocity of a surface acoustic wave of the surface acoustic wave element.
